(19) United States
(12) Patent Application Publication
(10) Pub. No.: US 2006/0290544 A1
(43) Pub. Date: Dec. 28, 2006

(54) Systems and methods for creating symbols and rendering models using such symbols

(76) Inventors: Ralf Scheidhauer, Hamburg (DE); Frank Toennies, Saarbruecken (DE)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/448,074

(22) Filed: Jun. 7, 2006

Related U.S. Application Data
(60) Provisional application No. 60/687,853, filed on Jun. 7, 2005.

(51) Int. Cl. H03M 7/00

(52) U.S. Cl. 341/82

(57) ABSTRACT

Systems and methods are provided for creating customized symbols and modeling business processes using such symbols. In one implementation, a computer-implemented method is provided for creating a customized symbol. The method may comprise selecting a symbol, the symbol comprising graphics data. The method may further comprise defining a customized symbol based on the selected symbol, wherein the step of defining comprises specifying at least one external property for the selected symbol, and storing the specified at least one external property in a style repository to enable rendering of the customized symbol on a canvas.

### CROSS REFERENCE TO RELATED APPLICATION(S)

This application claims the benefit of priority from U.S. Provisional Application No. 60/687,853, entitled “Computerized Systems and Methods for Displaying Objects and File Formats Related Thereto,” filed Jun. 7, 2005, the disclosure of which is expressly incorporated herein by reference to its entirety.

### BACKGROUND

I. Technical Field

The present invention generally relates to the field of computer graphics and to software tools for modeling processes, such as business processes. More particularly, the present invention relates to computerized systems and methods for creating symbols and graphically modeling business processes using such symbols.

II. Background Information

Many software and consulting companies use tools for strategy, design, implementation and controlling of business processes. A “business process” describes functions or activities that occur in a particular order and that create added value for a company. Since business processes are crucial to performance, companies often spend a significant amount of time and effort to design efficient business processes. Further, in order to efficiently design business processes, many companies use modeling tools. A “modeling tool” may include software and/or other computerized systems that can be used to plan a process. In general, modeling tools may depict, analyze, and optimize business processes. Often times a single tool can be used for modelling different business processes.

Some modeling tools allow users to model a business process in a graphical form using symbols to represent a logical sequence of steps in a process. Many of these tools contain symbols that represent the objects in a model. A user can create and modify models using a toolset built into the modeling tool or provided separately. Each model contains information about which objects and which connections are visualized in that model. For each object, the model stores information about which symbol is used to visualize the object, its position on the canvas, its size, and its style.

One example of a platform for building business processes is the ARIS Platform provided by IDS Scheer AG (Saarbruecken, Germany). The ARIS Platform provides a tool portfolio for designing, implementing, and controlling business processes. Within the ARIS platform is a repository that contains a graph and the nodes within the graph are called objects. The models are graphical representations of parts of the graph. Objects are represented in the models using symbols. A user may use symbols included with ARIS or create symbols of his own using an AMF editor that is part of the ARIS system.

Many users may require small modifications of the default symbols from a modeling tool installer or vendor. The user may need to change some attributes external to the symbol instances, such as color, line style, line width, shade, etc. These modifications, called variants of the original symbols, can be used to represent different semantics inside one model.

In prior solutions, if a user wanted to modify a symbol, the user would be required to duplicate the symbol, make minor modifications (for example. a color change) and then import the newly generated symbol as an additional symbol back into the system. This process, however, is time and skill intensive. Furthermore, there is no relationship between the source symbol and the copy of the symbol, and the design changes to the source symbol are not propagated automatically to the copy of the symbol.

In view of the foregoing, there is a need for improved systems and methods for generating models using symbols. Moreover, there is a need for improved systems and methods for generating customized symbols, including the ability to generate different visual representations out of the same symbol based on one or more external properties and saving the same for later use in a symbol repository.

### SUMMARY

Systems, methods and computer-readable media consistent with embodiments of the present invention may obviate one or more of the above and/or other issues and drawbacks. Consistent with an aspect of the invention, computerized systems and methods may be provided for rendering a model by using symbols. The symbols may be modified to create customized symbols using one or more external properties, as disclosed herein.

In accordance with one embodiment, a method is provided for creating customized symbols. The customized symbols may be used to render a model on a canvas. The method may comprise selecting a symbol and defining a customized symbol based on the selected symbol. The step of selecting a symbol may comprise at least one of: selecting a symbol from a symbol repository to provide the selected symbol; combining a symbol from a symbol repository with one or more other symbols or graphics to provide the selected symbol; and importing one or more graphics to provide the selected symbol. The step of defining a customized symbol may comprise specifying at least one external property for the selected symbol to define the customized symbol.

Consistent with another embodiment of the present invention, a system is provided for creating customized symbols. The system may comprise a processor and a memory, wherein the memory comprises instructions that are configured to cause the processor to perform a method. The method may comprise selecting a symbol and defining a customized symbol based on the selected symbol. The step of selecting a symbol may comprise at least one of: selecting a symbol from a symbol repository to provide the selected symbol; combining a symbol from a symbol repository with one or more other symbols or graphics to provide the selected symbol; and importing one or more graphics to provide the selected symbol. The step of defining a customized symbol may comprise specifying at least one external property for the selected symbol to define the customized symbol.

While embodiments of the inventions are described herein with reference to modeling business processes, they can be created for other purposes as well. For example, customized symbols that are created consistent with the invention can be used in a basic graphic context or in a presentation, such as a Windows PowerPoint presentation.

Additional objects and advantages of the invention will be set forth in part in the description which follows, and in part will be obvious from the description, or may be learned by practice of embodiments of the invention. The objects and advantages of the invention will be realized and attained by means of the elements and combinations particularly pointed out in the appended claims.

It is to be understood that both the foregoing general description and the following detailed description are exemplary and explanatory only and are not restrictive of the invention, as claimed.

### BRIEF DESCRIPTION OF THE DRAWINGS

The accompanying drawings, which are incorporated in and constitute a part of this disclosure, illustrate various embodiments and aspects of the present invention. In the drawings:

FIG. 1 illustrates an exemplary system environment, consistent with an embodiment of the present invention;

FIG. 2 is an exemplary hardware and software architecture, consistent with an embodiment of the present invention;

FIG. 3 is a flow diagram of an exemplary method for creating customized symbols, consistent with an embodiment of the present invention;

FIG. 4 is an exemplary graphical user interface for a symbol editor, consistent with an embodiment of the present invention; and

FIG. 5 is another exemplary system environment, consistent with the embodiment of the present invention.

### DESCRIPTION OF THE EMBODIMENTS

The following detailed description refers to the accompanying drawings. Wherever possible, the same reference numbers are used in the drawings and the following description to refer to the same or similar parts. While several exemplary embodiments and features of the invention are described herein, modifications, adaptations and other implementations are possible, without departing from the spirit and scope of the invention. For example, substitutions, additions or modifications may be made to the components illustrated in the drawings, and the exemplary methods described herein may be modified by substituting, reordering, or adding steps to the disclosed methods. Accordingly, the following detailed description does not limit the invention. Instead, the proper scope of the invention is defined by the appended claims.

Systems and methods consistent with embodiments of the invention enable a user to create customized symbols. The customized symbols may be stored in a symbol repository and, together with other customized symbols or other symbols, used to render models and other graphics on a canvas. As used herein, the term “canvas” refers to any medium for displaying information, including computer screens and other electronic display panels (e.g., an LCD or plasma panel). To define a customized model, the user may change one or more elements of a selected symbol and then use the new customized symbol with other symbols for rendering a model or other graphics. In one embodiment, the model may be representative of business process or other process.

In embodiments of the present invention, a “symbol” may depict a unique object in a graphical form. A symbol may include a text description that names or describes a function performed by an object that is modeled by the symbol. An “object” refers to a concept that can be expressed or implemented as part of a process, such as a business process. A symbol may further comprise a graphical element formed of, for example, a large rectangle with rounded corners and a small quadratic icon on the left upper corner.

Consistent with embodiments of the present invention, a modeling tool may be implemented to provide a user with a workspace to create, modify and update symbols. Symbols may be stored and available for user selection from a symbol repository. The symbol repository may be accessed through a portion of a work space included in a graphical user interface. For example, the symbol repository may include symbols that have been arranged or categorized based on color groups. In one embodiment, the symbol repository comprises a standardized set of symbols provided by a software vendor, installer or other source. A user may modify one or more selected symbols from the symbol repository to create new customized symbols. Once a user has modified a symbol, the new symbol may be saved for later modification in the symbol repository.

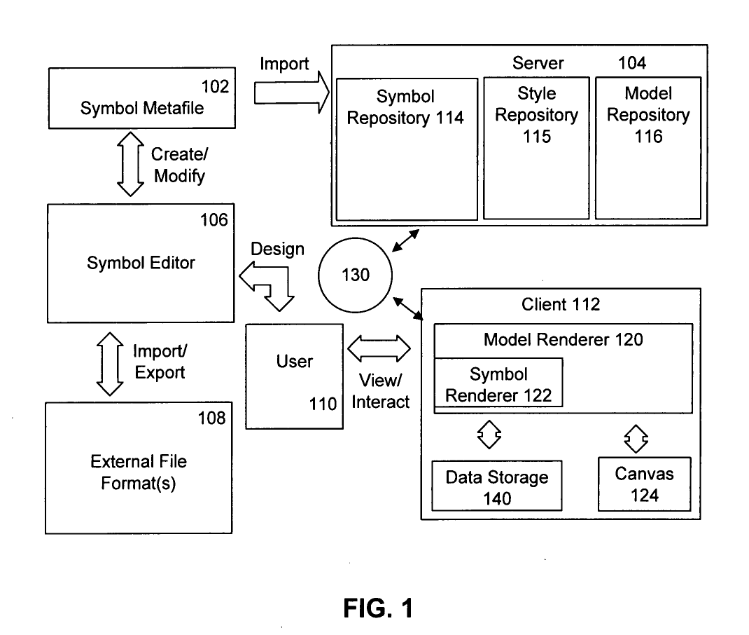

FIG. 1 depicts an exemplary system environment 100, consistent with an embodiment of the present invention. Several of the components in system 100 can be implemented with, for example, the ARIS system architecture available from IDS Scheer. Further, the ARIS metafile format (AMF) may be used to define graphical symbols. As will be appreciated by one skilled in the art, however, embodiments of the invention are not limited to the ARIS environment and/or AMF, and may be applied in other environments, including computerized or software-based environment with modeling and/or graphical tools. As used herein, the term “software” encompasses any and all types of software, including computer software, computer program products, and program modules and components, including business and financial software applications and components.

As shown in FIG. 1, system 100 may include a symbol metafile 102, a server 104, symbol editor 106, external file format(s) 108, a user 110, and a client 112. User 110 may operate client 112. Symbol metafile 102 may be based on, for example, an ARIS metafile of the ARIS system. Further, symbol editor 106 may comprise the AMF editor of the ARIS system, and client 112 may be the ARIS client of the ARIS system.

Symbol metafile 102 may comprise one or more XML-based files in vector graphic format. Symbol metafile 102 may provide for the definition of graphical symbols used in system 100. By way of example, the format of the symbol metafile 102 may use a small subset of the Scaleable Vector Format (SVG) language and include various system specific extensions, for example, ARIS specific extensions to these standard elements. A symbol may be composed by graphic primitives called “elements.” Each element may have its own set of attributes that define the visual and logical representation of the element. Each symbol may be defined through a combination of such elements. In accordance with an embodiment of the invention, the symbol format may define the following primitive graphic elements: rectangles, rounded rectangles, lines and polygons, ellipses and circles, and bitmaps, including various graphics.

For purposes of illustration, the following table shows an exemplary XML markup for an AMF symbol (shown to the right of the XML-markup):

```
  1  <?xml version=‘1.0’ ?>
  2  <svg amf:innerBoundingBox=“22,20,174,96”
  3  xmlns=“http://www.w3.org/2000/svg” version=“1.1”
  4  xmlns:amf=“http://www.ids-scheer.de/aris/amf/ns.htm”
  5  xmlns:svg=“http://www.w3.org/2000/svg”
  6  xmlns:xlink=“http://www.w3.org/1999/xlink”>
  7
  8  <svg:rect
  9  fill=“#96ff96”
10  amf:fill-replaceable=“1”
11  stroke=“#000000”
12  stroke-width=“1”
13  stroke-linecap=“round”
14  amf:stroke-replaceable=“1”
15  x=“0” y=“0”
16  width=“249” height=“155”
17  amf:rectRoundRadius=“60”
18  amf:rectRoundingFixed=“true”
19  />
20  <svg:polygon
21  fill=“#ffff00”
22  amf:fill-replaceable=“false”
23  stroke=“#000000”
24  stroke-width=“1”
25  amf:stroke-replaceable=“false”
26  points=“187,137 211,97 230,137 ”
27  amf:fixedCorner=“point (249,155)”
28  />
29  </svg>
```

As shown by the above example, the XML-markup for the symbol includes a header (lines 1-6) followed by the two elements constituting the symbol (i.e., a green-filled rectangle (lines 8-19) and a yellow-filled polygon (lines 20-28).

by way of example, the following table summarizes AMF extensions that may be added to standard SVG elements to implement the components of FIG. 1 based on an ARIS system environment:

| Extension Attribute | Description | Valid Values | Default |
|---|---|---|---|
| stroke-replaceable | Configures the AMF | 1) Numerical integer values with | “false” |
| | renderer to use an user | a value above 0. | |
| | defined stroke when | 2) Boolean value “true” or “false” | |
| | rendering the tagged | Numerical values configure the | |
| | graphic primitive object. | renderer to use the external user | |
| | The user defined stroke | defined stroke with the given | |
| | itself may override stroke | number (if the renderer is | |
| | color, stroke style, stroke | configured with a set of user | |
| | strength, stroke dash- | defined strokes) | |
| | array etc. | “false” configures the renderer to | |
| | | ignore any user defined strokes | |
| | | and only use the stroke that's | |
| | | defined inside the AMF file. | |
| | | “true” is a synonym for “1” and is | |
| | | only supported for backward | |
| | | compatibility. | |
| fill-replaceable | Configures the AMF | 1) Numerical integer with a | “false” |
| | renderer to use the user | value above 0. | |
| | defined brush of the given | 2) Boolean value - “true” or | |
| | value when rendering the | “false” | |
| | tagged graphic primitive | Numerical values configure the | |
| | object. | renderer to use the external user | |
| | The user defined brush | defined brush | |
| | itself describes a set of | (the brush defines fill color, fill | |
| | attributes that determines | pattern, fill transparency) with the | |
| | the for example fill color, | given number (if the renderer is | |
| | fill style, fill transparency | configured with a set of user | |
| | etc. | defined brushes) | |
| | | “false” configures the renderer to | |
| | | ignore any user defined brushes | |
| | | and only use the brush that's | |
| | | defined inside the AMF file. | |
| | | “true” is a synonym for “1” and is | |
| | | only supported for backward | |
| | | compatibility | |
| fixedCorner | 1) Any attribute value | One value out of the following | “none” |
| | other than “none” | tree categories: | (normal |
| | describes the | 1) “point([x cord], [y cord])” that | linear |
| | surrounding graphical | defines the coordinates of the | scaling) |
| | element as not | anchor point. The | |
| | scaleable. | coordinates are logical | |
| | 2) The value of this | coordinates and therefore | |
| | attribute defines the | relative to the upper left | |
| | anchor point that is | corner of the symbol | |
| | used by the renderer | 2) A symbolic constant that | |
| | to position this non | represents a well known | |
| | scaleable symbol. | point inside the AMF. Valid | |
| | | constants are: | |
| | | a. “lowerLeft” | |
| | | b. “lowerRight” | |
| | | c. “upperLeft” | |
| | | d. “upperRight” | |
| | | e. “center” | |
| | | The constants “lowerLeft, | |
| | | lowerRight”, “upperLeft” and | |
| | | “upperRight” represents the | |
| | | coordinates of the | |
| | | corresponding corners of the | |
| | | AMFs outer bounding box, | |
| | | the constant “center” | |
| | | represents the coordinates | |
| | | the center of the overall AMF | |
| | | has. | |
| | | “none” - configures the | |
| | | render to scale the | |
| | | surrounding graphical | |
| | | element linear. (normal | |
| | | scaling) | |
| rectRoundRadius | This attribute is only valid | Numerical integer with a value | 0 (normal |
| | for <svg:rect .. /> | equal to or above zero. | rectangle, |
| | elements. | The value is interpreted as an | no rounded |
| | The standard SVG rect | circle radius. every corner of the | corners) |
| | element describes a | rectangle is replaced with the | |
| | rectangular share of given | corresponding quarter r of a circle | |
| | with and height. However, | with the given radius. | |
| | is doesn't provide a | The radius is specified in logical | |
| | mechanism to render | coordinates. | |
| | rounded rectangles. This | | |
| | attribute configures the | | |
| | renderer to round every | | |
| | corner of the defining | | |
| | rectangle with an circle of | | |
| | the given radius | | |
| rectRoundingFixed | This attribute is only valid | 1) “true” The rounding radius of | “true” |
| | for <svg:rect .. /> | the tagged rectangles is | |
| | elements that represents | fixed and will not scaled by | |
| | a rounded rectangle (that | the renderer even if the | |
| | also have a valid | surrounding AMF is scaled. | |
| | “rectRoundRadius” | 2) “false” the rounding radius of | |
| | attribute) | the rectangle is scaled | |
| | It defines if the rounding | linearly according to the | |
| | radius of rectangle should | horizontal and vertical scale | |
| | be increased if the | factors of the surrounding | |
| | rectangle is scaled to a | Symbol. | |
| | width/height that is | | |
| | extending the default | | |
| | width. | | |
| innerBoundingBox<[ | Every AMF Symbol can | Each inner bounding box is | If this |
| 1-9]*> | have one or more explicit | represented by the upper left | attribute |
| | inner bounding boxes. | corner oft the box and its | isn't set the |
| | This boxes are used by | horizontal and vertical extend. | renderer |
| | the renderer to determine | innerBoundingBox = “22, 20, 174, 96” | will |
| | the graphical boundaries | represents a box starting at the | calculate |
| | of textual attributes that | logical coordinates X = 22, Y = 20 | the inner |
| | may be renderer inside | that is 174 logical coordinates | box |
| | the AMF Symbol. | wide and has a height of 96 | according |
| | One innerBoundingBox | logical coordinates. | to a |
| | attributes defines one | The logical coordinate (0/0) | predefined |
| | rectangle of these | represents the top left corner | algorithm |
| | Rectangles. | from the outer bounding box. | |
| | The first inner rectangle is | | |
| | defined by the | | |
| | innerBoundingBox | | |
| | attribute, additional boxes | | |
| | can be defined by the | | |
| | innerBoundingBox[N] | | |
| | command. | | |

In addition to SVG or SVG with extensions, symbol metafile 102 may be based on other conventional and known vector graphics or metafile formats, such as cgm (computer graphics metafile), dpx (digital picture), igs (initial graphics), and swf (small web format).

Symbol editor 106, which may be implemented as a software component running on a computer or provided with the software components executed by client 112 (see below), may allow users to create customized symbols according to his or her own needs or other requirements. In one embodiment, symbol editor 106 enables user 110 to select and modify existing symbols in symbol repository 114. Once the external properties of a symbol from the symbol repository 114 has been modified, those changes can be saved as an instance of that symbol to the style repository 115, as discussed further below. Additionally, symbol editor may allow user 110 to combine a symbol from symbol repository 114 with one or more other symbols or graphics to provide a selected symbol for customization, and/or import one or more graphics in external file format(s) 108 to provide the selected symbol for customization. In either case, user 110 may specify at least one external property for the selected symbol to define the customized symbol for storage and later usage.

Changes to existing symbols may include, for example, the addition of company logos to a symbol or the changing colors or shades in a symbol. Additionally, as described above, it may be possible to reuse already existing graphics or symbols stored in external file format(s) 108. For example, symbol editor 106 may enable user 110 to import graphics stored in GIF, JPG, BMP and EMF (a Microsoft proprietary vector graphics file format) to create customized symbols that are defined via symbol metafile 102 and stored in symbol repository 114 for use in system 100. In yet another embodiment, user 110 may create a completely new symbol using graphics tools and/or a library of primitives provided by symbol editor 106 to define the elements of the symbol. Once a new symbol is created, symbol editor 106 may save the new symbol to the symbol repository 114. In addition, for symbols that are only modified by changing one or more external properties, those changes may be reflected as a new instance of the symbol store in style symbol 115, with the data for the basic graphic primitives or elements of the symbol being retained in symbol repository 114.

In one embodiment, symbol editor 106 may comprise a general purpose computer (e.g., a personal computer, network computer, server, or mainframe computer) having a processor (not shown) that may be selectively activated or reconfigured by a computer program to perform one or more methods for allowing the user to create symbols or modify existing symbols, as described above. Alternatively, symbol editor 106 may be implemented with software that is executed by client 112.

As further shown in system 100, server 104 and client 112 may be connected to a network 130. Network 130 may facilitate the communication between these components, including the exchange of instructions, graphics and other data. Further, network 130 may support the operation between client 112 and server 104 according to a typical client-server relationship. One of skill in the art will appreciate that although one server and client are depicted in FIG. 1, any number of servers and clients may be provided. Furthermore, one of ordinary skill in the art will recognize that functions provided by one or more components of system 100 may be combined.

As indicated above, network 130 provides communications between the various entities in system 100, such as server 104 and client 112. Network 130 may be a shared, public, or private network and encompasses a wide area or local area. Further, network 130 may be implemented through any suitable combination of wired and/or wireless communication networks and may comprise a local area network (LAN), a wide area network (WAN), an intranet, or the Internet. Communication between server 104 and client 112 may be implemented using conventional protocols or technology, such as TCP/IP.

Server 104 may comprise a general purpose computer (e.g., a personal computer, network computer, server, or mainframe computer) having a processor (not shown) that may be selectively activated or reconfigured by a computer program to perform one or more methods consistent with the present invention. Server 104 may also be implemented in a distributed network. Alternatively, server 104 may be specially constructed for carrying-out methods consistent with the present invention. Furthermore, server 104 may include a symbol repository 114 that comprises a database that stores data defining basic graphical primitives or elements of symbols used in system 100. Server 104 may also include a style repository 115 that comprises a database that stores data for defining default values for the external properties (fill color, line widths, shading, etc) of symbols stored in symbol repository 114, as well as data reflecting customized symbols based on user-defined external properties. Consistent with an aspect of the invention, each such customized symbol may be stored as a different instance in the style repository 115. In another embodiment, symbol repository and style repository may be combined to provide a single database that stores both basic graphics data and external property data for each symbol.

As disclosed herein, symbols stored in server 104 may be used by model renderer 120 of client 112 to generate and render models. Each model may be defined by data that is stored in model repository 116 of server 104. A toolset provided in model renderer 120 or by other software (e.g., a model editor) may enable user 110 to create each model by, for example, selecting symbols and/or symbol instances to be included in the model, as well as defining the layout, arrangement and/or relationship between the various symbols in the model.

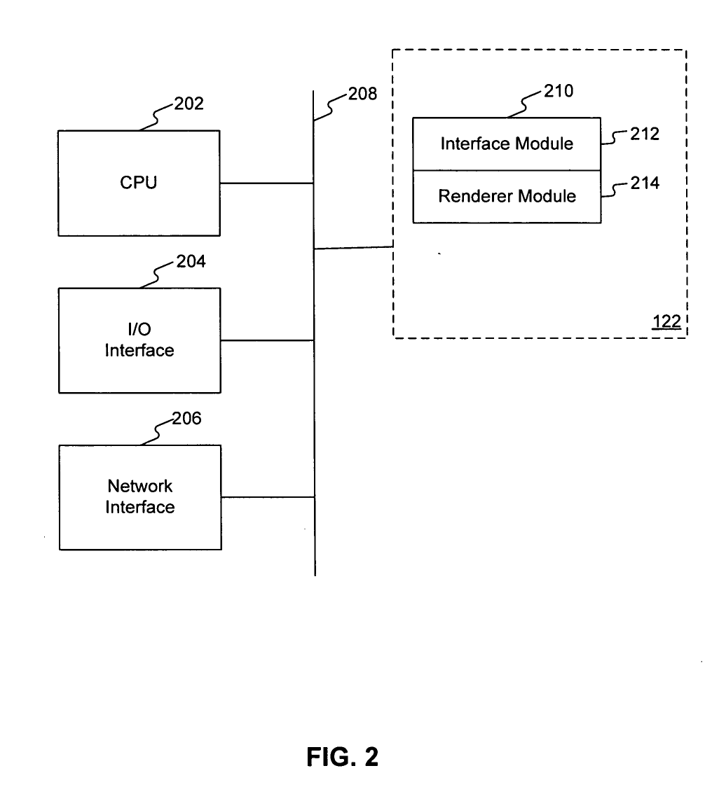

Consistent with embodiments of the invention, client 112 may be any type of device for communicating with server 104 over network 130. For example, client 112 may be a personal computer, handheld device, or any other appropriate computing platform or device capable of exchanging data with network 130. Client 112 may include one or more hardware and/or software components, such as model renderer 120, data storage 140, and canvas 124. Further, model renderer 120 may include symbol renderer 122. Symbol renderer 122, may be, for example, the AMF renderer of the ARIS system. Details concerning symbol renderer 122 and other components of client 112 are discussed further below. Further, program modules for, implementing symbol renderer 122 are discussed in further detail with respect to FIG. 2.

FIG. 2 shows exemplary hardware and software architecture related to symbol renderer 122, consistent with an embodiment of the present invention. The software components of FIG. 2 (interface module 212 and renderer module 214) may be packaged as part of the software systems or subsystems of symbol renderer 122. The hardware devices of FIG. 2 (CPU 202, I/O interface 204, network interface 206, bus 208, memory 210) may be implemented as part of a computer or other hardware of client 112.

As shown in the example of FIG. 2, the hardware architecture may include at least one central processing unit (CPU) 202, an I/O interface 204, a network interface 206, and a memory 210. Memory 210 may be implemented as part of data storage 140 or otherwise provided separately as part of client 112. CPU 202 may execute instructions associated with the software processes contained in memory 210 and transmit results to other subsystems of symbol renderer 122 or client 112 over a high speed interconnect or data bus 208. I/O interface 204 is an interface that may be used to couple symbol renderer 122 to devices such as a keyboard, a mouse, a display device, and any other I/O device useful to user 110 in operating and managing symbol renderer 122, as will be appreciated by one skilled in the art. Further, network interface 206 may be used to communicate with network 130 (FIG. 1).

To create customized symbols, memory 210 may store executable or programmed instructions in the form of one or more software modules 212 and 214. Software modules 212 and 214 may be written using any known programming language. As shown in FIG. 2. memory 210 includes an interface module 212 and a renderer module 214.

Interface module 212 may comprise programmed instructions for causing the display of repositories of symbols on canvas 124 for use in the modeling tool. Renderer module 214 may have program instructions that, when executed, render symbols according to the user-specified criteria, as will be described further below. Renderer module 214 may use data from symbol metafile 102 and stored in symbol repository 114 and style repository 115 to render a symbol on canvas 124. Additionally, or alternatively, render module 214 may use x and y coordinates defined by a user that specify where to draw a symbol on canvas 124, and/or sx and sy scaling factors defined by a user that specify whether a symbol is drawn stretched or shrunken in the x and y direction. Moreover, renderer module 214 may also exclude from scaling any elements specified by a user when rendering a symbol.

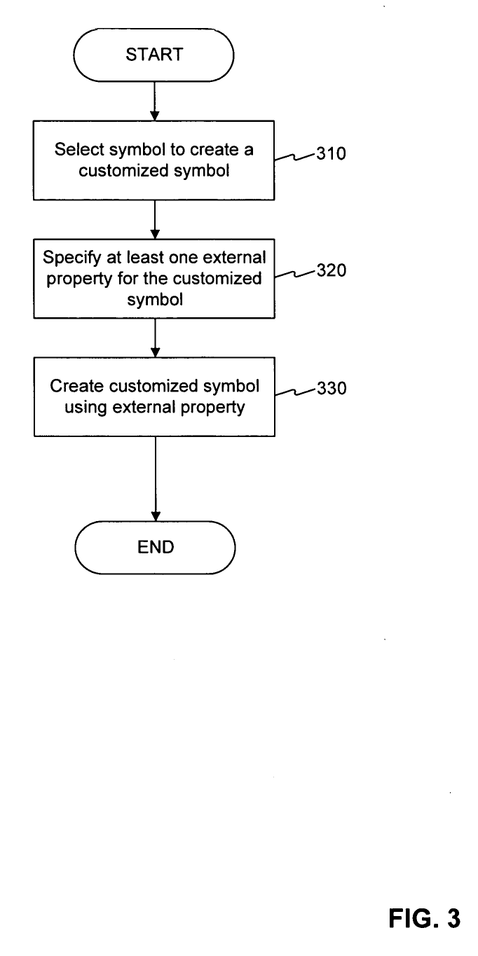

Referring now to FIG. 3, a flow diagram is provided of an exemplary method for creating customized symbols, consistent with an embodiment of the present invention. As further described below, the exemplary method of FIG. 3 allows a user to create a customized symbol. The customized symbol may then be saved to symbol repository 114 (along with any instance of the symbol in style repository 115) for later use. A model or other graphic may then be rendered with the customized symbol, when taken alone or in combination with other symbols in symbol repository 114 and/or instances in style repository 115.

At the start of the process, a user (e.g., user 110) may first select a symbol to customize (step 310). As part of this step, user 110 may select a symbol from a symbol repository, such as symbol repository 114. Symbol repository may comprise standardized symbols from a software vendor, installer or other source, and may also include previously stored or modified symbols, including previously created customized symbols by the user. Additionally, or alternatively, the user may combine a symbol from a symbol repository 114 with one or more other symbols or graphics to create a new symbol. As a still further option, the user may import a graphic or symbol from external file format 108 using symbol editor 106 to provide a selected symbol for customization. In one embodiment, symbol editor 106 may also comprise tools to enable user 110 to define a text or graphics window on a symbol. Once defined, the text or graphics window may be used to insert specific text or graphics on the symbol via the window.

For each new symbol that is created, the new symbol may be saved to the symbol repository 114 for later use and customization. Each new symbol may be stored with a default set of external properties, that may be recorded in style repository 115 as a base instance (e.g., instance 0 or 1). All data for new symbols may be imported to server 104 using symbol metafile 102 (see FIG. 1).

As disclosed herein, each symbol may be composed of graphical primitives called “elements.” Each element has its own set of attributes that define the visual and logical representation of that element. Once a user has selected a symbol for customization (i.e, either an existing symbol or new symbol stored in symbol repository 114), the user may specify aspects of the selected symbol to define a customized symbol, such as at least one external property for the customized symbol (step 320). By way of example. an external property may comprise a style attribute or any other external attribute. A style attribute may comprise at least one of a fill color, stroke width and outline color. An external attribute may comprise at least one of combining another symbol or imported graphic with the existing symbol or adding text to the symbol.

Once the user has specified the at lest one external property, symbol editor 106 may create the customized symbol using each external property specified by the user (step 330). Symbol editor 106 may then save data for the customized symbol to a repository for later use. If the user created a new symbol (as described above), graphics data for the new symbol may also be saved back to symbol repository 114. If the user selected a symbol from symbol repository 114 and changed at least one external property for that symbol, then a new instance of the symbol is saved back to style repository 115.

In one embodiment, a user 110 may also modify an instance of a symbol saved in style repository 115. For example, the user may modify an external property associated with a selected instance and save the updates to the instance under the same filename. In this scenario, any changes to that instance may be propagated to any model that incorporates that instance.

Upon execution, symbol renderer 122 may use the defined external property to render the symbol. As mentioned above, each symbol may have a default set of external properties, such as default brush B1 . . . Bn and pen values P1 . . . Pn. If these any one of these values have not been specified in an instance of a customized symbol (brush k, pen i) saved in style repository 115 (i.e. k>n, i>m) then the default values are used. Otherwise. the updated or modified values in the instances stored in style repository 115 are used (i.e., brush k and pen i).

For example, if the external property is a fill color, symbol renderer 122 may render the customized symbol using a fill color specified by the user. Therefore, the customized symbol may have a different fill color than the original symbol. Further, if a fill color has not been specified in the instance data for a customized symbol then default values for the fill color may be used.

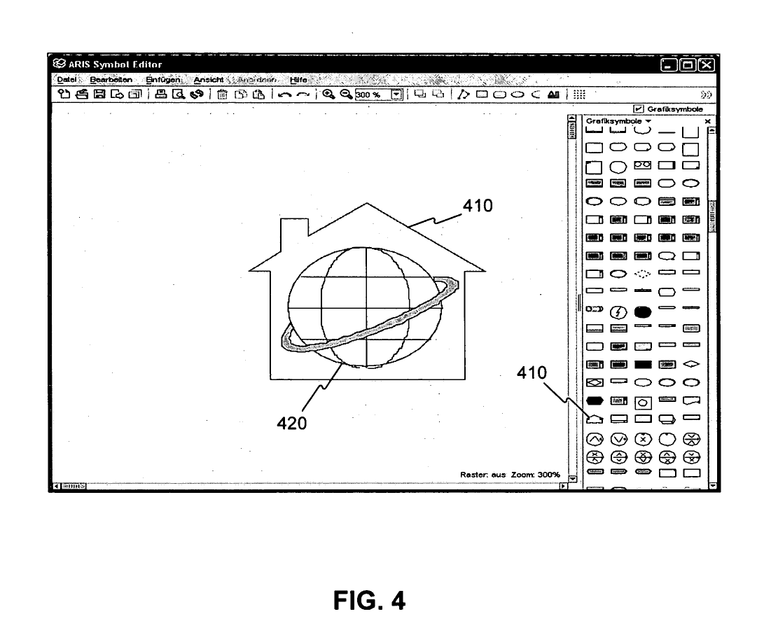

In order to perform steps 310-330, one or more graphical user interfaces (GUIs) may be provided to assist user 110 in selecting a symbol for customization and entering data to define or modify external properties of the symbol. By way of example, FIG. 4 illustrates a screen shot of an exemplary GUI for a symbol editor (such as symbol editor 106). The GUI of FIG. 4 may enable to a user to create a new symbol from scratch and customize it by specifying one or more external properties. For example, as represented in FIG. 4, the user may select a base symbol 410 from the symbol repository. The user may then decide to add a company logo 420 (e.g., import from an external file format) to symbol 410 to create a new symbol for storage and customization. Customization of the symbol may include, for example, defining one or more external properties for the symbol.

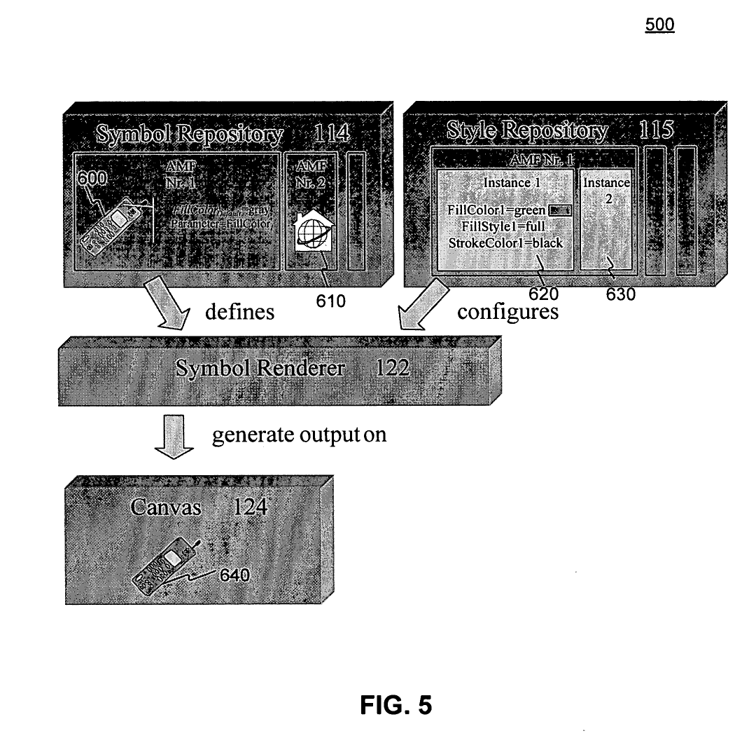

To further illustrate the principles and scope of the invention, FIG. 5 is a drawing of another exemplary system environment. As shown in FIG. 5, system 600 may include symbol repository 114, style repository 115, symbol renderer 122 and canvas 124. Symbol repository 114 may comprise a database that stores data for symbols used in system 600, including basic graphics data for each of the symbols. The graphics data may contain property data such as the default values for external properties of each symbol, which may also be stored in symbol repository 114, or such data may be stored as part of a base instance for the symbol in style repository. In either case, style repository 115 may comprise of a database that stores the style information for each symbol, including the modified external property data represented by instances of the customized symbols.

In the example of FIG. 5, symbol repository 114 holds one or more symbols, such as symbols 600 and 610. If the user has modified or customized either of the symbols using symbol editor 106, then the revised external properties of that symbol are stored in style repository 115 as one or more instances of the symbol. For example, for symbol 610, style repository 115 stores instance 620 (“Instance 1”) as well as instance 630 (“Instance 2”).

In this example, symbol 600 has an external property “fillcolor” that is defined with a default value of “gray” in symbol repository 114. To create a customized symbol based on symbol 600, the user may use symbol editor 106 to change one or more external properties, such as to define the “fillcolor” of “green.” This instance of symbol 610 is stored as “instance 1”(see reference numeral 620) in style repository 115. Other instances of symbol 610 may also be stored in style repository 115 to represent further customized symbols.

To render symbol 610 on canvas 124, symbol renderer 122 may first combine the graphic definition from symbol repository 114 with the style or configuration information of instance 1 (620) from style repository 115. Based on this information, symbol renderer 122 may generate the new customized symbol 640 on the canvas 124 that is consistent with the user-defined external properties stored in style repository 115.

In one embodiment, if a symbol is used that contains more than one instance in style repository 115, the user may specify which instance to use to generate a model or other graphic. For example, if symbol 610 has two instances defined in style repository 115, the user may specify whether to use the external properties form the first instance 620 or the second instance 630 when creating the model data or graphic data. Based on this data, the specific instance can be retrieved from style repository 115. Otherwise, if no instance is specified (if one or more are present), the default values in symbol repository 114 can be used to render the symbol.

The foregoing description of possible implementations consistent with the present invention does not represent a comprehensive list of all such implementations or all variations of the implementations described. The description of only some implementations should not be construed as an intent to exclude other implementations. One of ordinary skill in the art will understand how to implement the invention in the appended claims in may other ways, using equivalents and alternatives that do not depart from the scope of the following claims.

The systems and methods disclosed herein may be embodied in various forms including, for example, a data processor, such as a computer that also includes a database. Moreover, the above-noted features and other aspects and principles of the present invention may be implemented in various environments. Such environments and related applications may be specially constructed for performing the various processes and operations according to the invention or they may include a general-purpose computer or computing platform selectively activated or reconfigured by code to provide the necessary functionality The processes disclosed herein are not inherently related to any particular computer or other apparatus, and may be implemented by a suitable combination of hardware, software, and/or firmware. For example, various general-purpose machines may be used with programs written in accordance with teachings of the invention, or it may be more convenient to construct a specialized apparatus or system to perform the required methods and techniques.

Systems and methods consistent with embodiments of the present invention also include computer readable media that include program instruction or code for performing various computer-implemented operations based on the methods and processes disclosed herein. The media and program instructions may be those specially designed and constructed for the purposes of the invention, or they may be of the kind well known and available to those having skill in the computer software arts. Examples of program instructions include, for example, machine code, such as produced by a compiler, and files containing a high level code that can be executed by the computer using an interpreter.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A method of creating a customized symbol, comprising the steps of:
selecting a symbol, the symbol comprising graphics data;
defining a customized symbol based on the selected symbol, wherein the step of defining comprises specifying at least one external property for the selected symbol; and
storing the specified at least one external property in a style repository to enable rendering of the customized symbol on a canvas.

2. The method of claim 1, wherein the step of selecting a symbol comprises at least one of:
selecting a symbol from a symbol repository to provide the selected symbol,
combining a symbol from a symbol repository with one or more other symbols or graphics to provide the selected symbol; and
importing one or more graphics to provide the selected symbol.

3. The method of claim 1, further comprising:
storing the graphics data in a symbol repository.

4. The method of claim 1, wherein the symbol comprises one or more elements defined by the graphics data.

5. The method of claim 4, wherein the specified at least one external property updates an appearance of the one or more elements when the customized symbol is rendered on the canvas.

6. The method of claim 1, wherein the specified at least one external property is one of a fill color, stroke width, outline color, graphic addition, or text addition.

7. The method of claim 1, wherein the step of storing the specified at least one external property comprises storing the specified at least one property as an instance of the customized symbol in the style repository.

8. The method of claim 7, further comprising:
specifying additional external properties; and
storing the specified additional external properties as one or more additional instances of the customized symbol in the style repository.

9. A system for creating a customized symbol, the system comprising:
a processor; and
a memory comprises instructions that are adapted to cause the processor to perform a method comprising:
selecting a symbol, the symbol comprising graphics data;
defining a customized symbol based on the selected symbol, wherein the step of defining comprises specifying at least one external property for the selected symbol; and
storing the specified at least one external property in a style repository to enable rendering of the customized symbol on a canvas.

10. The system of claim 9 further comprising, wherein the step of selecting a symbol comprises at least one of:
selecting a symbol from a symbol repository to provide the selected symbol,
combining a symbol from a symbol repository with one or more other symbols or graphics to provide the selected symbol; and
importing one or more graphics to provide the selected symbol.

11. The system of claim 9 storing the graphics data in a symbol repository.

12. The system of claim 9 wherein the symbol comprises one or more elements defined by the graphics data.

13. The system of claim 12, wherein the specified at least one external property updates an appearance of the one or more elements when the customized symbol is rendered on the canvas.

14. The system of claim 9, wherein the specified at least one external property is one of a fill color, stroke width, outline color, graphic addition, or text addition.

15. The system of claim 9, wherein the step of storing the specified at least one external property comprises storing the specified at least one property as an instance of the customized symbol in the style repository.

16. A computer-readable medium comprising programmable instructions adapted to perform a method for creating a customized symbol, comprising:
selecting a symbol, the symbol comprising graphics data;
defining a customized symbol based on the selected symbol, wherein the step of defining comprises specifying at least one external property for the selected symbol; and
storing the specified at least one external property in a style repository to enable rendering of the customized symbol on a canvas.

17. The computer-readable medium of claim 16, wherein the step of selecting a symbol comprises at least one of:
selecting a symbol from a symbol repository to provide the selected symbol,
combining a symbol from a symbol repository with one or more other symbols or graphics to provide the selected symbol; and
importing one or more graphics to provide the selected symbol.

18. The computer-readable medium of claim 16, further comprising:
storing the graphics data in a symbol repository.

19. The computer-readable medium of claim 16, wherein the symbol comprises one or more elements defined by the graphics data.

20. The computer-readable medium of claim 19, wherein the specified at least one external property updates an appearance of the one or more elements when the customized symbol is rendered on the canvas.
